(19) United States
(12) Patent Application Publication
(10) Pub. No.: US 2016/0154440 A1
(43) Pub. Date: Jun. 2, 2016

(54) RETAINING STRUCTURE AND SERVER STRUCTURE HAVING THE SAME

(71) Applicants: Inventec (Pudong) Technology Corporation, Shanghai (CN); Inventec Corporation, Taipei City (TW)

(72) Inventors: CHUNG-SHENG NI, Taipei City (TW); Chih-Pin Wei, Taipei City (TW); Chun-Ying Yang, Taipei City (TW); Chang-Hsin Chiu, Taipei City (TW)

(21) Appl. No.: 14/684,451

(22) Filed: Apr. 13, 2015

(30) Foreign Application Priority Data
Nov. 27, 2014 (CN) 201410697581.9

(51) Int. Cl. G06F 1/18; H05K 7/14

(52) U.S. Cl. CPC G06F 1/183; H05K 7/1417

(57) ABSTRACT

A retaining structure and a server structure having the same are provided herein. The retaining structure is used for retaining a circuit board on a chassis in the server structure. The circuit board includes a first connection portion and a second connection portion for respectively mating with a first connector and a second connector. The retaining structure includes a plurality of side walls commonly defining a channel for accommodating a region of the circuit board, a backstop section located within the channel and abutting against a protrusion of the circuit board for buffering a mating force applied from the second connection portion to the first connection portion, and a damping snapper located on one of said side was for damping the retaining structure to the chassis.

### FIELD OF THE INVENTION

The present invention relates to a retaining structure and a server structure having the same, and particularly to a retaining structure for retaining a circuit board on a server structure.

### BACKGROUND OF THE INVENTION

Please refer to FIG. 1, which depicts a conventional server structure 10. The server structure 10 comprises at least one circuit board 20 used for extension, a first connector 30, a second connector 40, a chassis 50, and a main circuit board 55, The first connector 30 is disposed on the main circuit board 55, and the main circuit board 55 is fixed on the chassis 50.

As shown on FIG. 1, the profile of the circuit board 20 is knife-like shaped. The circuit board 20 comprises a first connection portion 21 and a second connection portion 22, where the first connection portion 21 is used for mating with the first connector 30, thereby connecting the circuit board 20 to the main circuit board 55 via the first connector 30. On the other hand, the second connection portion 22 of the circuit board 20 is used for mating with the second connector 40, thereby respectively electrically connecting the second connector 40 to the circuit board 20 and the main circuit board 55.

As shown on FIG. 1, in the conventional server structure 10, when the second connector 40 is horizontally plugged in or unplugged from the second connection portion 22 of the circuit board 20, a horizontal mating force will be applied on a vertical combination portion of the first connection portion 21 and the first connector 30 having terminals, so that the first connection portion 21 and the first connector 30 are offset relative to each other, thereby generating a bad electrical connection problem, and even damaging the contacting pads of the first connection portion 21 and/or the terminals of the first connector 30.

In the prior art, in order to solve the above technical problems, a tray or a bracket is usually implemented for retaining the circuit board 20. However, the structure of the conventional tray or bracket is complex, and huge quantities of material are consumed. Also, the purpose for retaining the circuit board 20 on the server structure 10 is achieved by using mounting processes. Accordingly, it is necessary to provide a retaining structure to solve the above technical problems.

### SUMMARY OF THE INVENTION

To resolve the above technical problems, an objective of the present invention is to provide a retaining structure for retaining a circuit board on a chassis of a server structure. By utilizing the retaining structure to be abutting against the circuit board, a mating force applied on the circuit board is buffered, thereby preventing a bad electrical connection problem, or preventing damage to contacting pads of the circuit board and/or terminals of a relative connector.

To achieve the above-mentioned inventive objective, the present invention provides a retaining structure for retaining a circuit board on a chassis. The circuit board comprises a first connection portion and a second connection portion for respectively mating with a first connector and a second connector. The retaining structure comprises: a plurality of side walls commonly defining a channel for accommodating a region of the circuit board, a backstop section located within the channel and abutting against a protrusion of the circuit board for buffering a mating force applied from the second connection portion to the first connection portion, and a damping snapper located on one of said side walls for clamping the retaining structure to the chassis.

In a preferable embodiment of the present invention, one of said side walls comprises a first fastening screw hole for receiving a first fastening screw to fasten the retaining structure with the circuit board.

In a preferable embodiment of the present invention, one of said side walls comprises a second fastening screw hole for receiving a second fastening screw to fasten the retaining structure to the chassis.

In a preferable embodiment of the present invention, one of said side walls is provided with a damping snapper on a first surface thereof, and a second surface opposite the first surface corresponds to the channel; and the clamping snapper further comprises a connection section connected with the first surface and a vertically elastic arm section for clamping the retaining structure to the chassis.

In a preferable embodiment of the present invention, the plurality of side walls further comprise a first side wall, a second side wall opposite the first side wall, and a third side wall connecting with the first side wall and the second side wall.

In a preferable embodiment of the present invention, an engagement section is formed on a wall surface of one of said side was for engaging within a geometric edge of the circuit board, and the engagement section and the geometric edge are structurally complementary.

Another objective of the present invention is to provide a server structure. The server structure comprises a retaining structure for retaining a circuit board on a chassis of the server structure. By utilizing the retaining structure to abut against the circuit board, a mating force applied on the circuit board is buffered.

To achieve the above-mentioned inventive objective, the present invention provides a server structure comprising: a chassis, where a recessed surface is formed thereon, a circuit board comprising a first connection portion and a second connection portion for respectively mating with a first connector and a second connector of the server structure, and a retaining structure comprising: a plurality of side walls commonly defining a channel for accommodating a region of the circuit board, a backstop section located within the channel and abutting against a protrusion of the circuit board for buffering a mating force applied from the second connection portion to the first connection portion, and a clamping snapper located on one of said side walls for clamping the retaining structure to the chassis.

In a preferable embodiment of the present invention, one of said side walls comprises a first fastening screw hole for receiving a first fastening screw to fasten the retaining structure with the circuit board.

In a preferable embodiment of the present invention, one of said side walls comprises a second fastening screw hole for receiving a second fastening screw to fasten the retaining structure to a hole of the chassis.

In a preferable embodiment of the present invention, one of said side walls is provided with a clamping snapper on a first surface thereof, and a second surface opposite the first surface corresponds to the channel; and the clamping snapper further comprises a connection section connected with the first surface and a vertically elastic arm section for clamping the retaining structure to the chassis.

In a preferable embodiment of the present invention, the plurality of side walls further comprise a first side wall, a second side wall opposite the first side wall, and a third side wall connecting with the first side wall and the second side wall.

In a preferable embodiment of the present invention, an engagement section is formed on a wall surface of one of said side walls for engaging within a geometric edge of the circuit board, and the engagement section and the geometric edge are structurally complementary.

### BRIEF DESCRIPTION OF THE DRAWINGS

FIG. 1 depicts a conventional server structure;

FIG. 2 depicts an assembly diagram of a retaining structure and a circuit board according to the present invention;

FIG. 3 depicts an assembly diagram of FIG. 2;

FIG. 4 depicts a partial assembly diagram of FIG. 2;

FIG. 5 depicts an exploded diagram of a server structure according to the present invention; and

FIG. 6 depicts an assembly diagram of FIG. 5.

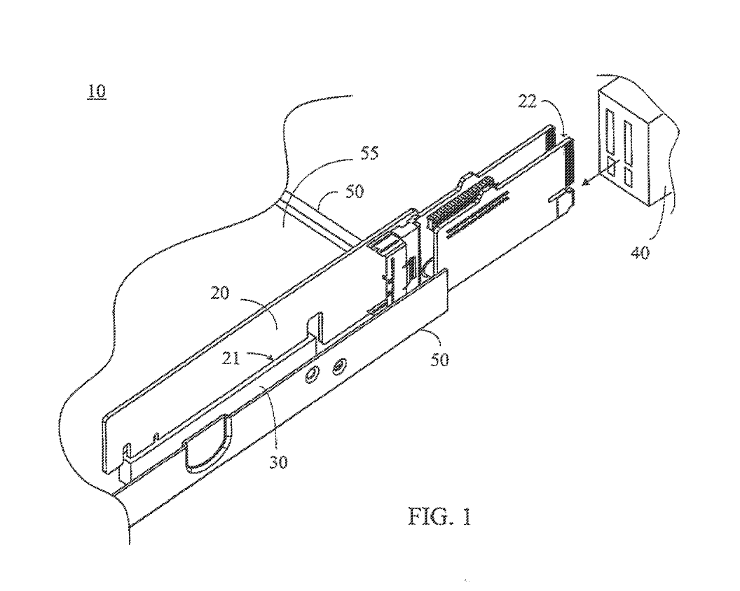

### DETAILED DESCRIPTION OF THE INVENTION

These and other features, aspects, and advantages of the present invention will become better understood with regard to the following description, appended claims, and accompanying drawings.

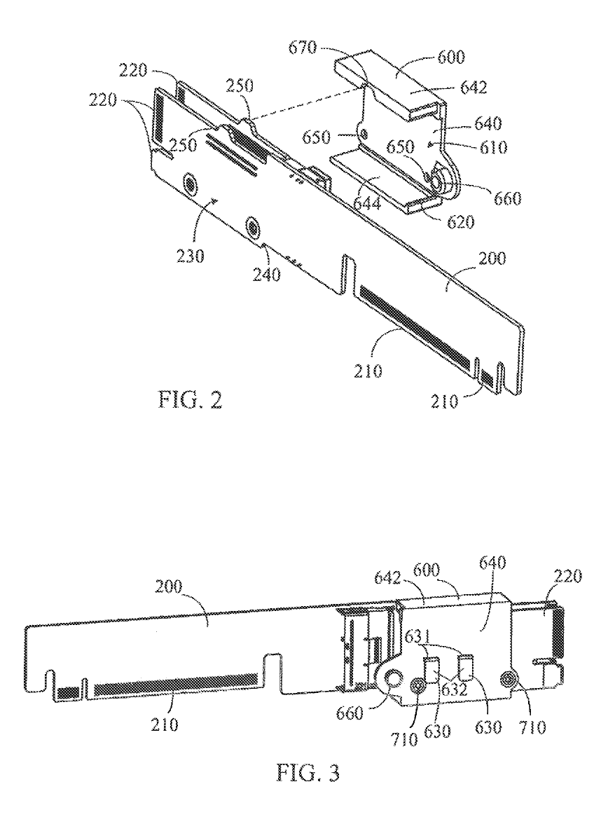

Please refer to FIG. 2 and FIG. 3. FIG. 2 depicts an assembly diagram of a retaining structure 600 and a circuit board 200 used for expansion according to the present invention. FIG. 3 depicts an assembly diagram of FIG. 2. The circuit board 200 comprises a first connection portion 210 and a second connection portion 220 for respectively mating with a first connector 300 and a second connector 400 (referring to FIG. 6). The retaining structure 600 comprises a first side wall 642, a second side wall 644 opposite the first side wall 642, a third side wall 640 connecting with the first side wall 642 and the second side wall 644, a backstop section 620, and a clamping snapper 630.

As shown on FIG. 2, the first side wall 642, the second side wall 644, and the third side wall 640 are laterally connected and define a channel 610 for accommodating a region 230 of the circuit board 220. The region 230 is located between the first connection portion 210 and the second connection portion 220 of the circuit board 200. Moreover, the backstop section 620 is located within the channel 610 and on an inner wall surface of the second side wall 644 and near the first connection portion 210 of the circuit board 200. The backstop section 620 is abutting against a protrusion 240 of the circuit board 220 for buffering a horizontal mating force applied from the second connection portion 220 to the first connection portion 210.

As shown on FIG. 2 and FIG. 3, the third side wall 640 comprises a first surface and a second surface, where the first surface is provided with a damping snapper 630, and the second surface corresponds to an inner space of the channel 610. It should be noted that there are a pair of clamping snappers 630 in this embodiment, but scope of the present invention is not limited by the number of damping snappers. Each damping snapper 630 further comprises a connection section 631 and a vertically elastic arm section 632. The connection section 631 is used for connecting the clamping snapper 630 with the first surface of the third side wall 640. The vertically elastic arm section 632 and the connection section 631 are connected to form a shaped (an inverted L-shaped) section. Also, the damping snapper 630 is used for elastically clamping the retaining structure 600 to a chassis 500 of a server structure 100 (referring to FIG. 6).

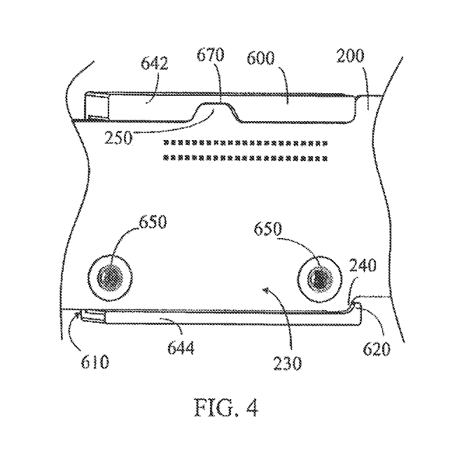

Please refer to FIG. 2 and FIG. 4. FIG. 4 depicts a partial assembly diagram of FIG. 2. A trapezoid geometric edge 250 is formed on one side of the region 230 of the circuit board 200 which is accommodated in the channel 610. Also, a trapezoid engagement section 670 is formed on an inner wall surface of the first side wall 642 of the retaining structure 600 corresponding to the geometric edge 250 of the circuit board 200. The engagement section 670 of the retaining structure 600 and the geometric edge 250 of the circuit board 200 are structurally complementary, thereby engaging the retaining structure 600 with the circuit board 200.

As shown on FIG. 2 and FIG. 3, a pair of holes are further formed on the region 230 of the circuit board 200. A pair of first fastening screw holes 650 are formed on the third side wall 640 of the retaining structure 600 in an area corresponding to the pair of holes of the circuit board 200. The retaining structure 600 is fixed on a circuit board 200 by using a pair of first fastening screws 710.

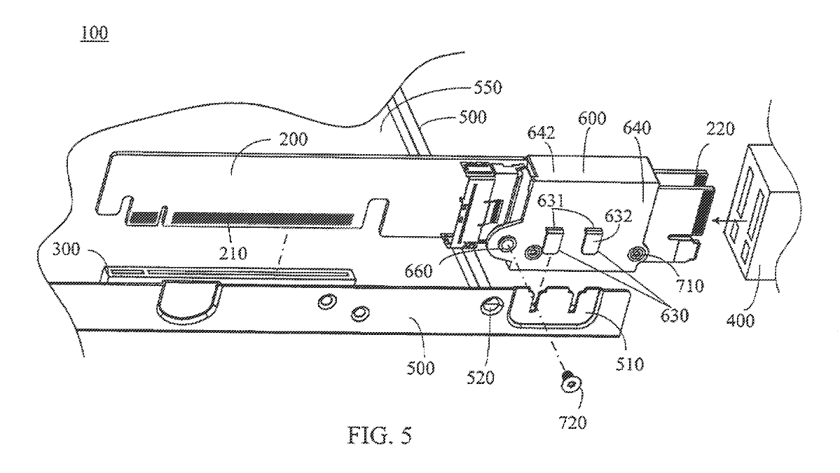

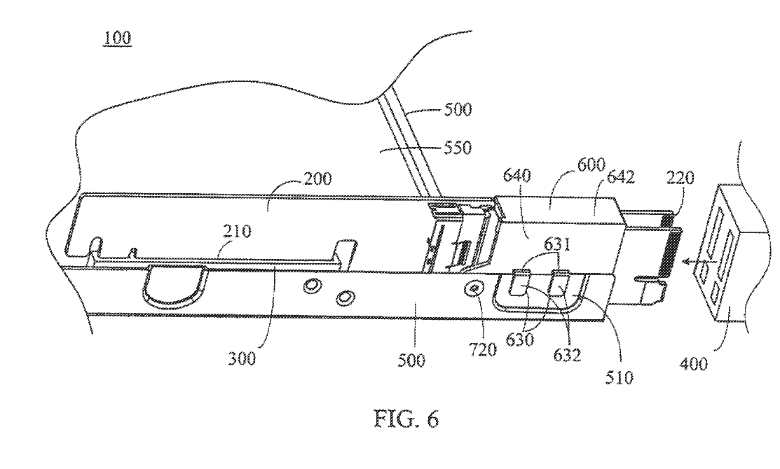

Please refer to FIG. 5 and FIG. 6. FIG. 5 depicts an exploded diagram of the server structure 100 according to the present invention. FIG. 6 depicts an assembly diagram of FIG. 5. The server structure 100 comprises the above circuit board 200 and retaining structure 600, and further comprises a first connector 300, a second connector 400, a chassis 500, and a main circuit board 550.

As shown on FIG. 5 and FIG. 6, the first connector 300 is disposed on the main circuit board 550, and the main circuit board 550 is fixed on the chassis 500. The circuit board 200 is attached to the main circuit board 550 via the first connector 300. Moreover, the second connection portion 220 of the circuit board 200 is assembled with the second connector 400, thereby respectively electrically connecting the second connector 400 with the circuit board 200 and the main circuit board 550. In addition, the assembly manner of the retaining structure 600 and the circuit board 200 are described above, and it will not be described in any further detail here.

As shown on FIG. 5 and FIG. 6, a recessed surface 510 is formed on a location where the retaining structure 600 is assembled with the recessed surface 510. After the first connection portion 210 of the circuit board 200 is plugged in the first connector 300, the clamping snapper 630 of the retaining structure 600 is elastically clamped on the recessed surface 510 of the chassis 500. To be specific, the retaining structure 600 is clamped on the chassis 500 by using the vertically elastic arm section 632 of the clamping snapper 630. Moreover, a hole 520 is formed on the chassis 500 near the recessed surface 510, and a second fastening screw hole 660 is formed on the first surface of the third side wall 640 of the retaining structure 600 in an area corresponding to the hole 520. The retaining structure 600 is fixed on the chassis 500 by using the hole 520 to receive a second fastening screw 720.

In this embodiment, by assembling the retaining structure 600 with the circuit board 200 and retaining the retaining structure 600 and the circuit board 200 on the chassis 500, a horizontal mating force applied from the second connector 400 to the first connector 300 is buffered when the second connector 400 is horizontally plugged in or unplugged from the second connection portion 220. Therefore, the first connection portion 210 and the first connector 300 will not be offset from each other due to the horizontal mating force, thereby preventing a bad electrical connection problem between the first connection portion 210 and the first connector 300, or preventing damage to contacting pads of the first connection portion 210 and/or terminals of the first connector 300.

In another embodiment, the retaining structure 600 of the present invention may be assembled with more than one circuit board. The circuit boards are retained on a chassis by using the retaining structures 600. Thus, a horizontal mating force applied from a second connector to a first connector is buffered. In addition, the retaining structure 600 of the present invention may be a one-piece plastic element, thereby decreasing a manufacturing cost of the server structure 100.

The above descriptions are merely preferable embodiments of the present invention, and are not intended to limit the scope of the present invention. Any modification or replacement made by those skilled in the art without departing from the spirit and principle of the present invention should fall within the protection scope of the present invention. Therefore, the protection scope of the present invention is subject to the appended claims.

What is claimed is:

1. A retaining structure for retaining a circuit board on a chassis, the circuit board comprising a first connection portion and a second connection portion for respectively mating with a first connector and a second connector, the retaining structure comprising:
a plurality of side walls commonly defining a channel for accommodating a region of the circuit board;
a backstop section located within the channel and abutting against a protrusion of the circuit board for buffering a mating force applied from the second connection portion to the first connection portion; and
a clamping snapper located on one of said side walls for clamping the retaining structure to the chassis.

2. The retaining structure according to claim 1, wherein one of said side walls comprises a first fastening screw hole for receiving a first fastening screw to fasten the retaining structure with the circuit board.

3. The retaining structure according to claim 2, wherein one of said side walls comprises a second fastening screw hole for receiving a second fastening screw to fasten the retaining structure to the chassis.

4. The retaining structure according to claim 1, wherein one of said side walls is provided with a clamping snapper on a first surface thereof, and a second surface opposite to the first surface corresponds to the channel; and the clamping snapper further comprises a connection section connected with the first surface and a vertically elastic arm section for clamping the retaining structure to the chassis.

5. The retaining structure according to claim 1, wherein the plurality of side walls further comprise a first side wall, a second side wall opposite to the first side wall, and a third side wall connecting with the first side wall and the second side wall.

6. The retaining structure according to claim 1, wherein an engagement section is formed on a wall surface of one of said side was for engaging within a geometric edge of the circuit board, and the engagement section and the geometric edge are structurally complementary.

7. A server structure, comprising:
a chassis, wherein a recessed surface is formed thereon;
a circuit board comprising a first connection portion and a second connection portion for respectively mating with a first connector and a second connector of the server structure; and
a retaining structure, comprising:
a plurality of side walls commonly defining a channel for accommodating a region of the circuit board;
a backstop section located within the channel and abutting against a protrusion of the circuit board for buffering a mating force applied from the second connection portion to the first connection portion; and
a clamping snapper located on one of said side walls for clamping the retaining structure to the chassis.

8. The server structure according to claim 7, wherein one of said side walls comprises a first fastening screw hole for receiving a first fastening screw to fasten the retaining structure with the circuit board.

9. The server structure according to claim 8, wherein one of said side walls comprises second fastening screw hole for receiving a second fastening screw to fasten the retaining structure to a hole of the chassis.

10. The server structure according to claim 7, wherein one of said side walls is provided with a clamping snapper on a first surface thereof, and a second surface opposite to the first surface corresponds to the channel; and the clamping snapper further comprises a connection section connected with the first surface and a vertically elastic arm section for clamping the retaining structure to the chassis.

11. The server structure according to claim 7, wherein the plurality of side walls further comprise a first side wall, a second side wall opposite the first side wall, and a third side wall connecting with the first side wall and the second side wall.

12. The server structure according to claim 7, wherein an engagement section is famed on a wall surface of one of said side walls for engaging within a geometric edge of the circuit board, and the engagement section and the geometric edge are structurally complementary.

13. A retaining structure for retaining a circuit board on a chassis, the circuit board comprising a first connection portion and a second connection portion for respectively mating with a first connector and a second connector, the retaining structure comprising:
a plurality of side walls commonly defining a channel for accommodating a region of the circuit board; and
a backstop section located within the channel and abutting against a protrusion of the circuit board for buffering a mating force applied from the second connection portion to the first connection portion,
wherein one of said side walls comprises a first fastening screw hole for receiving a first fastening screw to fasten the retaining structure with the circuit board; and
one of said side walls comprises a second fastening screw hole for receiving a second fastening screw to fasten the retaining structure to the chassis.

14. The retaining structure according to claim 13, further comprising a clamping snapper located on one of said side walls for clamping the retaining structure to the chassis.

15. The retaining structure according to claim 13, wherein one of said side walls is provided with a clamping snapper on a first surface thereof, and a second surface opposite the first surface corresponds to the channel; and the clamping snapper further comprises a connection section connected with the first surface and a vertically elastic arm section for clamping the retaining structure to the chassis.

16. The retaining structure according to claim 13, wherein the plurality of side walls further comprise a first side wall, a second side wall opposite the first side wall, and a third side wall connecting with the first skis wall and the second side wall.

17. The retaining structure according to claim 13, wherein an engagement section is formed on a wall surface of one of said side walls for engaging within a geometric edge of the circuit board, and the engagement section and the geometric edge are structurally complementary.
